(19) United States
(12) Patent Application Publication
(10) Pub. No.: US 2026/0304857 A1
(43) Pub. Date: Oct. 1, 2026

(54) SEMICONDUCTOR DEVICE

(71) Applicant: Mitsubishi Electric Corporation, Tokyo (JP)

(72) Inventors: Takuichiro SHITOMI, Tokyo (JP); Manabu YOSHINO, Tokyo (JP); Toshihiro IMASAKA, Tokyo (JP); Atsushi ITO, Tokyo (JP)

(73) Assignee: Mitsubishi Electric Corporation, Tokyo (JP)

(21) Appl. No.: 19/387,222

(22) Filed: Nov. 12, 2025

(30) Foreign Application Priority Data
Mar. 28, 2025 (JP) 2025-055258

(51) Int. Cl. H10D 62/10; H10D 30/65; H10D 64/00

(52) U.S. Cl. CPC H10D 62/109; H10D 30/65; H10D 64/112

(57) ABSTRACT

A semiconductor device includes a semiconductor substrate; a low voltage region provided in the semiconductor substrate; a high voltage region provided in the semiconductor substrate; a RESURF region provided in the semiconductor substrate and separating the low voltage region and the high voltage region; a source electrode electrically connected to the low voltage region; a drain electrode electrically connected to the high voltage region; a gate electrode connected to the semiconductor substrate between the low voltage region and the high voltage region; an oxide film provided on the RESURF region; and a first field plate provided on the oxide film, wherein the oxide film includes a first portion and a second portion that protrudes toward the RESURF region with respect to the first portion and is thicker than the first portion, and the first field plate is provided so as to expose the first portion.

### BACKGROUND

### Field

The present disclosure relates to a semiconductor device.

### Background

JP 2011-91159 A discloses a lateral semiconductor device in which a drift region is provided between a well region and a body region. Gate insulating films and field insulating layers are alternately provided on a surface of the drift region. Polysilicon is provided on a surface of the gate insulating film. The end of each polysilicon is provided so as to cover a portion of the surface side of the field insulation layer. The layer thickness of each field insulation layer is set to be greater than the film thickness of the adjacent gate insulating film. The lower end of each field insulation layer extends into the drift region.

In JP 2011-91159 A, a LOCOS (Local Oxidation Of Silicon) is formed by the gate insulating film and the field insulating layer. Here, in JP 2011-91159 A, polysilicon, which is a field plate of the gate, also exists on a thin film region of the LOCOS, that is, on the gate insulating film. At this time, there is a possibility that a potential difference between the gate insulating film and a SOI (Silicon On Insulator) layer directly thereunder becomes large. This could increase the possibility of gate oxide film breakdown and the electric field strength of the SOI layer. Therefore, it may be difficult to achieve high breakdown voltages such as 600V or 1200V, which are required for HVICs (High Voltage Integrated Circuits).

### SUMMARY

The present disclosure has been made to solve the above-mentioned problem, and an object thereof is to provide a semiconductor device capable of suppressing a decrease in breakdown voltage.

The features and advantages of the present disclosure may be summarized as follows.

According to an aspect of the present disclosure, a semiconductor device includes a semiconductor substrate of a first conductivity type; a low voltage region provided on an upper surface side of the semiconductor substrate; a high voltage region provided on the upper surface side of the semiconductor substrate; a RESURF region of a second conductivity type provided on the upper surface side of the semiconductor substrate and separating the low voltage region and the high voltage region; a source electrode electrically connected to the low voltage region; a drain electrode electrically connected to the high voltage region; a gate electrode connected to the upper surface of the semiconductor substrate via a gate oxide film between the low voltage region and the high voltage region; an oxide film provided on an upper surface of the RESURF region; and a first field plate provided on an upper surface of the oxide film, wherein the oxide film includes a first portion and a second portion that protrudes toward the RESURF region with respect to the first portion and is thicker than the first portion, and the first field plate is provided so as to expose the first portion.

Other and further objects, features and advantages of the disclosure will appear more fully from the following description.

### BRIEF DESCRIPTION OF DRAWINGS

FIG. 1 is a cross-sectional view of the semiconductor device according to Embodiment 1.

FIG. 2 is a cross-sectional view of the semiconductor device according to a first modification of Embodiment 1.

FIG. 3 is a cross-sectional view of the semiconductor device according to a second modification of Embodiment 1.

FIG. 4 is a cross-sectional view of the semiconductor device according to a third modification of Embodiment 1.

FIG. 5 is a cross-sectional view of the semiconductor device according to Embodiment 2.

FIG. 6A to 6H are cross-sectional views illustrating a method of manufacturing the semiconductor device according to Embodiment 2.

FIG. 7 is a cross-sectional view of the semiconductor device according to Embodiment 3.

FIG. 8 is a cross-sectional view of the semiconductor device according to Embodiment 4.

FIG. 9 is a plan view of the semiconductor device according to Embodiment 5.

FIG. 10 is a cross-sectional view obtained by cutting FIG. 9 along line A-B.

FIG. 11 is a plan view of the semiconductor device according to Embodiment 6.

FIG. 12 is a cross-sectional view obtained by cutting FIG. 11 along line A-B.

FIG. 13 is a cross-sectional view obtained by cutting FIG. 11 along line C-D.

FIG. 14 is a plan view of the semiconductor device according to Embodiment 7.

FIG. 15 is a cross-sectional view obtained by cutting FIG. 14 along line A-B.

FIG. 16 is a plan view of the semiconductor device according to Embodiment 8.

FIG. 17 is a cross-sectional view obtained by cutting FIG. 16 along the line A-B.

### DESCRIPTION OF EMBODIMENTS

Semiconductor devices according to each embodiment will be described with reference to the drawings. The same reference numerals are assigned to the same or corresponding components, and the repeated description may be omitted.

### Embodiment 1

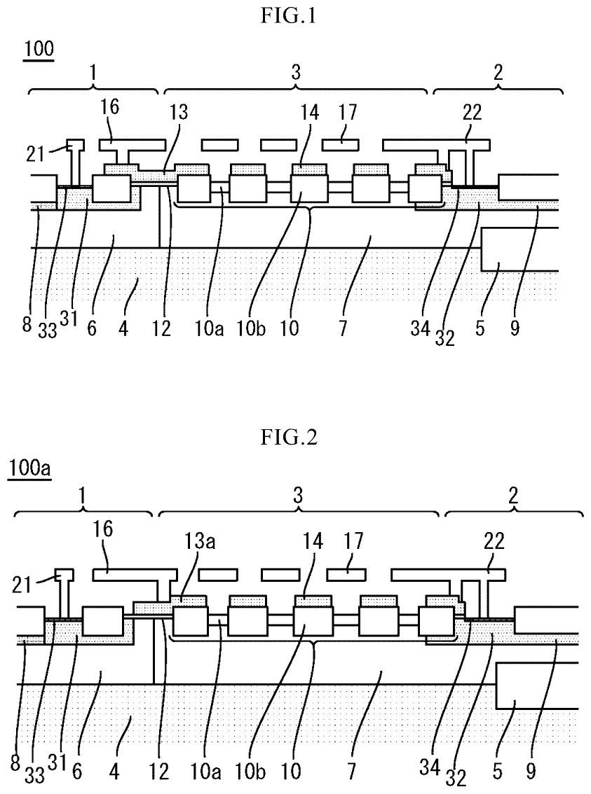

FIG. 1 is a cross-sectional view of a semiconductor device 100 according to Embodiment 1. The semiconductor device 100 is, for example, a high breakdown voltage lateral MOSFET (Metal-Oxide-Semiconductor Field-Effect Transistor). The semiconductor device 100 is used, for example, in an HVIC chip that drives and controls power devices such as an IGBT (Insulated Gate Bipolar Transistor) and a power MOSFET.

Hereinafter, the first conductivity type will be described as P-type, and the second conductivity type as N-type. However, the present disclosure is not limited to this, and the first conductivity type may be N-type, and the second conductivity type may be P-type. The semiconductor substrate 4 is, for example, a P-type silicon substrate. A well layer 6, which is a P-type diffusion layer, and a RESURF region 7, which is an N-type diffusion layer, are formed on the upper surface side of the semiconductor substrate 4. The RESURF region 7 is also called a well layer.

An N-type source layer 31 is formed on the upper surface side of the well layer 6. A high concentration layer 33, which is an N+ type diffusion layer, is formed on the upper surface side of the source layer 31. A source electrode 21 is connected to the high concentration layer 33. An N-type drain layer 32 is formed on the upper surface side of the RESURF region 7. A high concentration layer 34, which is an N+ type diffusion layer, is formed on the upper surface side of the drain layer 32. A drain electrode 22 is connected to the high concentration layer 34.

The area where the source layer 31 or the well layer 6 is provided corresponds to a low voltage region 1 provided on the upper surface side of the semiconductor substrate 4. The source electrode 21 is electrically connected to the low voltage region 1. The reference voltage of the low voltage region 1 is GND. The area where the drain layer 32 is provided corresponds to a high-voltage region 2 provided on the upper surface side of the semiconductor substrate 4. The drain electrode 22 is electrically connected to the high-voltage region 2.

The RESURF region 7 is formed, for example, between the well layer 6 and the drain layer 32, and under the drain layer 32. The RESURF region 7 constitutes a high-breakdown-voltage isolation region 3 surrounding the high-voltage region 2. The RESURF region 7 is provided on the upper surface side of the semiconductor substrate 4 and separates the low-voltage region 1 and the high-voltage region 2. The reference voltage of the high voltage region 2 is electrically isolated from GND by the RESURF region 7. Therefore, the high voltage region 2 is electrically floating. Such a structure is also called a RESURF isolation structure.

On the upper surface side of the well layer 6, a P-type inversion prevention layer 8 is formed on the opposite side of the drain layer 32 with respect to the source layer 31. On the upper surface side of the RESURF region 7, an N-type inversion prevention layer 9 is formed on the opposite side of the source layer 31 with respect to the drain layer 32. Further, in the high voltage region 2, a buried layer 5, which is an N+ type diffusion layer, is formed between the RESURF region 7 and the semiconductor substrate 4.

The gate electrode 13 is connected to the upper surface of the semiconductor substrate 4 with the gate oxide film 12 interposed between the low voltage region 1 and the high voltage region 2. The gate electrode 13 only needs to be connected to the channel region, that is, the portion between the source layer 31 and the RESURF region 7 on the upper surface of the well layer 6. An aluminum wiring 16, which is a gate wiring, is formed on the gate electrode 13.

An oxide film 10 is provided on the upper surface of the RESURF region 7. In the example of FIG. 1, the oxide film 10 is also formed on the upper surfaces of the low voltage region 1 and the high voltage region 2. The oxide film 10 is also called a LOCOS oxide film. The oxide film 10 includes a first portion 10a and a second portion 10b that protrudes toward the RESURF region 7 with respect to the first portion 10a and is thicker than the first portion 10a. The first portions 10a and the second portions 10b are alternately provided.

A conductive field plate 14 is provided on the upper surface of the oxide film 10. The field plate 14 is formed to stabilize a potential gradient of the RESURF region 7. The field plate 14 is provided so as to expose the thin first portion 10a. A field plate 17 is provided above the field plate 14. An insulating film such as a silicon oxide film formed by chemical vapor deposition (CVD) is provided between the field plate 14 and the field plate 17. The field plate 14 and the field plate 17 are capacitively coupled.

Next, a method of manufacturing the semiconductor device 100 will be described. First, the buried layer 5 is formed on the semiconductor substrate by ion implantation. Next, epitaxial growth is performed. Furthermore, the well layer 6, the RESURF region 7, the inversion prevention layer 8, and the inversion prevention layer 9 are formed by ion implantation into the epitaxial growth layer. However, either the well layer 6 or the RESURF region 7 may be formed by using the epitaxial growth layer as it is without using ion implantation.

Thereafter, the oxide film 10, which is an element isolation LOCOS oxide film, is formed by thermal oxidation using a nitride film as a mask. At this time, thermal oxidation processing is performed with the nitride film mask partially left also in the region where the oxide film 10 is formed. Furthermore, thermal oxidation processing is performed again after removing the nitride film mask. As a result, the first portion 10a, which is a partial thin film region, can be formed in the oxide film 10.

Next, the gate oxide film 12 of the MOSFET is formed by thermal oxidation processing. Next, doped polysilicon is deposited by CVD to form the gate electrode 13 of the MOSFET. Also, the field plate 14 is formed of the same doped polysilicon layer as the gate electrode 13. The gate electrode 13 and the field plate 14 may be formed simultaneously. At this time, the field plate 14 is not formed on the thin first portion 10a of the oxide film 10.

Then, high concentration layers 33 and 34 and aluminum wiring 16 for connection to the source terminal, drain terminal, and gate terminal of the MOSFET are formed. Also, the field plate 17 is formed of the same aluminum wiring layer as the aluminum wiring 16. The aluminum wiring 16 and the field plate 17 may be formed simultaneously.

Next, the effects of the present embodiment will be described. According to the present embodiment, a thin first portion 10a is present in the oxide film 10. That is, the lower surface of the thermal oxide film formed on the surface of the RESURF region 7 is partially recessed. Therefore, the volume of the RESURF region 7, which is a drift layer, can be increased, and the on-resistance of the semiconductor device 100 can be reduced. Also, for a MOSFET having the same on-resistance, the area of the RESURF region 7 in plan view can be shrunk. Therefore, the chip cost can be reduced.

In addition, the field plate 14 enables stabilization of the potential gradient in the RESURF region 7. Furthermore, in the present embodiment, the field plate 14 does not exist on the thin first portion 10a. Therefore, it is possible to suppress dielectric breakdown of the first portion 10a due to the potential difference between the field plate 14 and the RESURF region 7. Therefore, the withstand voltage between the field plate 14 and the RESURF region 7 can be ensured, and the same withstand voltage as that of a conventional MOSFET without the first portion 10a can be maintained. That is, a decrease in withstand voltage can be suppressed.

Also, the field plate 14 and the field plate 17 are capacitively coupled. This makes it possible to form a potential distribution having a gradient from the high voltage region 2 toward the low voltage region 1. Therefore, the potential gradient of the RESURF region 7 can be further stabilized, and the breakdown voltage of the semiconductor device 100 can be increased.

Furthermore, the field plate 17 is provided directly above the first portion 10a, avoiding directly above the field plate 14. In other words, the field plates 14 and 17 are alternately arranged while partially overlapping. Thereby, the field plates 14, 17 can be capacitively coupled in multiple stages from the high voltage side toward the low voltage side. Therefore, the potentials of the field plates 14, 17 can be gradually lowered.

Here, FIG. 1 shows an example in which the field plate 14 is not provided on the upper surface of the first portion 10a. Not limited to this, the provision of the field plate 14 so as to expose the first portion 10a of the oxide film 10 may include a state in which the field plate 14 partially covers the first portion 10a. For example, the field plate 14 may be provided so as to expose a part of each first portion 10a and cover another part thereof.

Also, some layers in the semiconductor device 100 may be omitted, and other layers may be added. For example, the field plate 17 may be omitted. Further, the material, shape, and the like of each layer described in the present embodiment are merely examples and are not limited thereto. For example, the numbers of the first portions 10a and the second portions 10b in the oxide film 10 are not limited. Also, the widths of the respective first portions 10a may be different, and the widths of the respective second portions 10b may be different. The semiconductor substrate 4 may be made with a wide bandgap semiconductor. The wide bandgap semiconductor is silicon carbide, a gallium nitride-based material, or diamond.

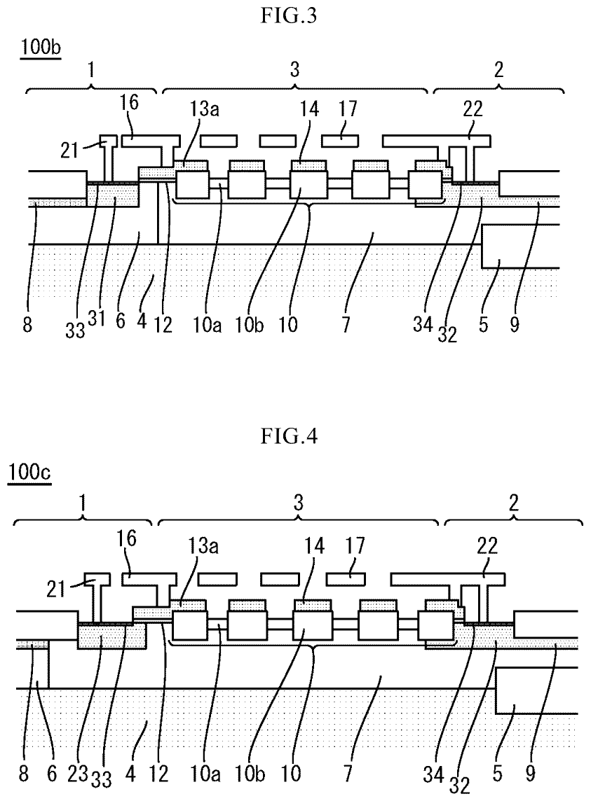

FIG. 2 is a cross-sectional view of a semiconductor device 100a according to a first modification of Embodiment 1. As shown in FIG. 2, the gate electrode 13a may not be formed on the oxide film in the low voltage region 1. FIG. 3 is a cross-sectional view of a semiconductor device 100b according to a second modification of Embodiment 1. The oxide film does not have to be formed on the source layer 31 of the low voltage region 1.

FIG. 4 is a cross-sectional view of a semiconductor device 100c according to a third modification of Embodiment 1. In the semiconductor device 100c, a p-type body layer 23 is formed on the upper surface side of the RESURF region 7. The N+ type high concentration layer 33 is formed on the upper surface side of the body layer 23. The source electrode 21 is connected to the high concentration layer 33. A MOSFET may be formed in this way. In the third modification, the region where the body layer 23 is formed becomes the low voltage region 1.

Which of the present embodiment and the first to third modifications is adopted may be determined in consideration of the breakdown voltage, threshold voltage, on-resistance, presence or absence of parasitic operation, and the like of the MOS structure. Further, the gate electrode 13 may be used as a gate electrode of a fine MOSFET driven at a low voltage, an upper electrode of a capacitive element, or a lower electrode in a region other than the high-voltage isolation region shown in FIG. 1 and the like.

The above-described modifications can be applied as appropriate to the semiconductor devices according to the following embodiments. Note that the semiconductor devices according to the following embodiments have many points in common with Embodiment 1, so the description will focus on the differences from Embodiment 1.

### Embodiment 2

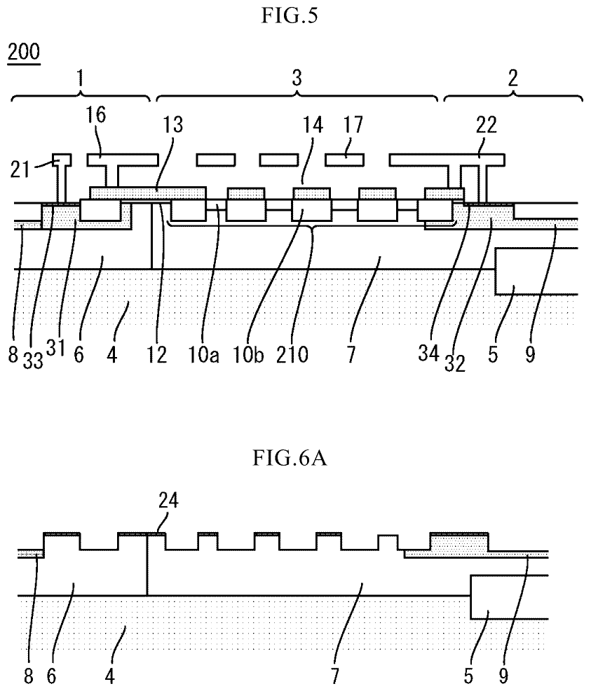

FIG. 5 is a cross-sectional view of a semiconductor device 200 according to Embodiment 2. As the oxide film 210 of the present embodiment, STI (Shallow Trench Isolation) may be used instead of the LOCOS of Embodiment 1. The oxide film 10 of Embodiment 1 also had irregularities formed on the upper surface. In contrast, the upper surface of the oxide film 210 of the present embodiment is flat.

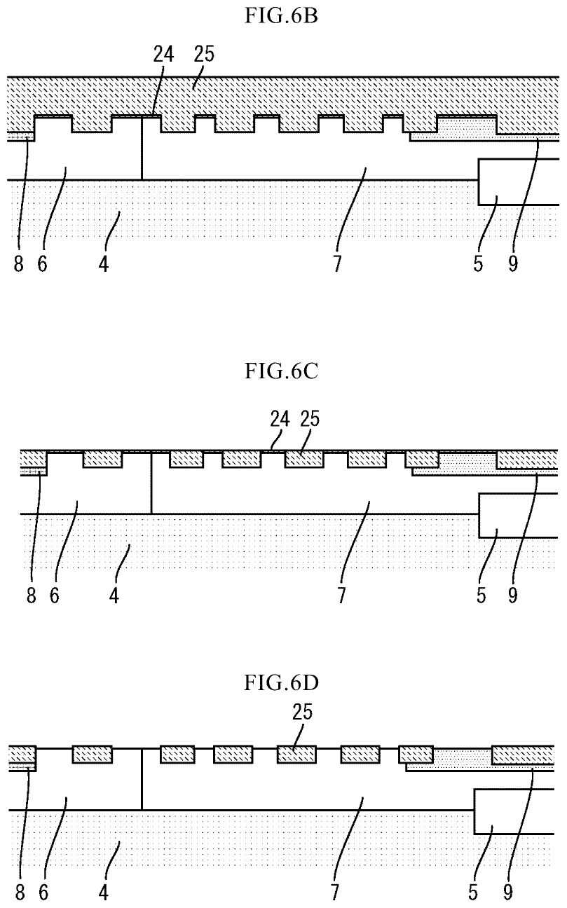

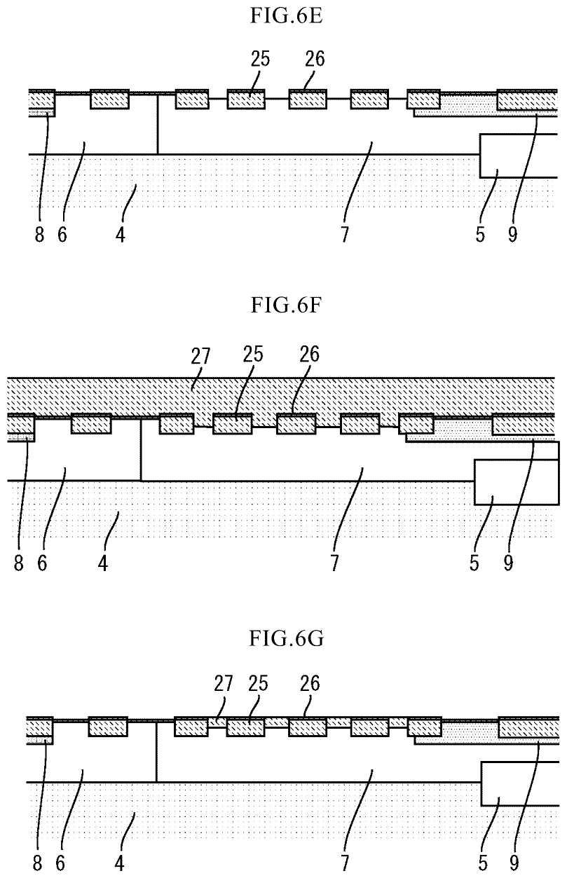

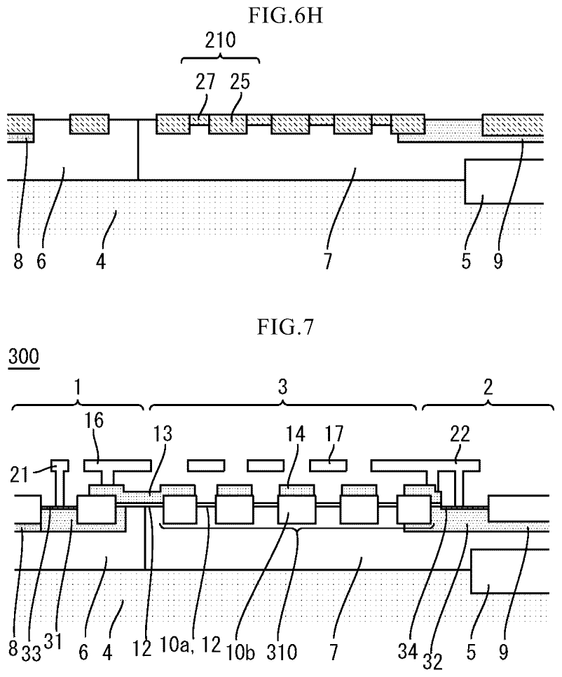

Next, a method of manufacturing the semiconductor device 200 will be described. FIGS. 6A to 6H are cross-sectional views illustrating a method of manufacturing the semiconductor device 200 according to Embodiment 2. First, as shown in FIG. 6A, silicon etching is performed using a laminated film 24 made of an oxide film, a nitride film, or the like as a mask. Thereby, a trench is formed. Next, the trench sidewalls are oxidized by thermal oxidation. Thereafter, as shown in FIG. 6B, an oxide film 25 is deposited by CVD to fill the inside of the trench with the oxide film 25.

Next, as shown in FIG. 6C, the oxide film 25 is planarized by chemical mechanical polishing (CMP) using the laminated film 24 as a stopper. Next, as shown in FIG. 6D, the laminated film 24 is etched and removed. Next, a nitride film 26 is formed, which is opened only in a portion corresponding to a newly formed shallow trench. Then, as shown in FIG. 6E, silicon etching is performed using the opened nitride film 26 as a mask to form a shallow trench.

Next, as shown in FIG. 6F, thermal oxidation and an oxide film deposition process are performed again to fill the shallow trench with an oxide film 27. Next, as shown in FIG. 6G, the oxide film 27 is flattened by CMP processing again using the nitride film 26 as a stopper. Next, as shown in FIG. 6H, the nitride film 26 is removed. Thus, the oxide film 210 is formed. That is, it can be said that the oxide film 210 has a structure using two types of STIs with different depths. The oxide film 210 can be formed by repeating a normal STI manufacturing method twice.

In the present embodiment, by using STI for the oxide film 210, other circuit regions can be miniaturized compared to LOCOS, and the chip area can be reduced.

### Embodiment 3

FIG. 7 is a cross-sectional view of a semiconductor device 300 according to Embodiment 3. In the oxide film 310 of the present embodiment, a first portion 10a is formed of the gate oxide film 12. That is, the first portion 10a is the same type of layer as the gate oxide film 12 and has the same thickness as the gate oxide film 12. According to the present embodiment, the step of forming only the first portion 10a can be omitted, and the process cost can be reduced.

By replacing the first portion 10a with the gate oxide film 12, the oxide film thickness becomes even thinner. However, since the field plate 14 does not exist on the first portion 10a, the breakdown voltage reduction of the MOSFET can be suppressed. Further, since the oxide film thickness of the first portion 10a becomes thin, the recess of the oxide film 10 becomes large, and the volume of the RESURF region 7 further increases. Accordingly, the on-resistance of the MOSFET can be further reduced.

### Embodiment 4

FIG. 8 is a cross-sectional view of a semiconductor device 400 according to Embodiment 4. The semiconductor device 400 includes an N-type semiconductor layer 18 on the upper surface side of the RESURF region 7 and directly below the first portion 10a. The semiconductor layer 18 is a diffusion layer with a higher concentration than the RESURF region 7. The semiconductor layer 18 is formed in a recessed region of the oxide film 10. Therefore, the semiconductor layer 18 does not inhibit depletion of the RESURF region 7, and does not decrease the breakdown voltage of the MOSFET. Furthermore, the semiconductor layer 18 increases the N-type carrier concentration in the drain drift region. Therefore, the on-resistance of the MOSFET can be further reduced.

### Embodiment 5

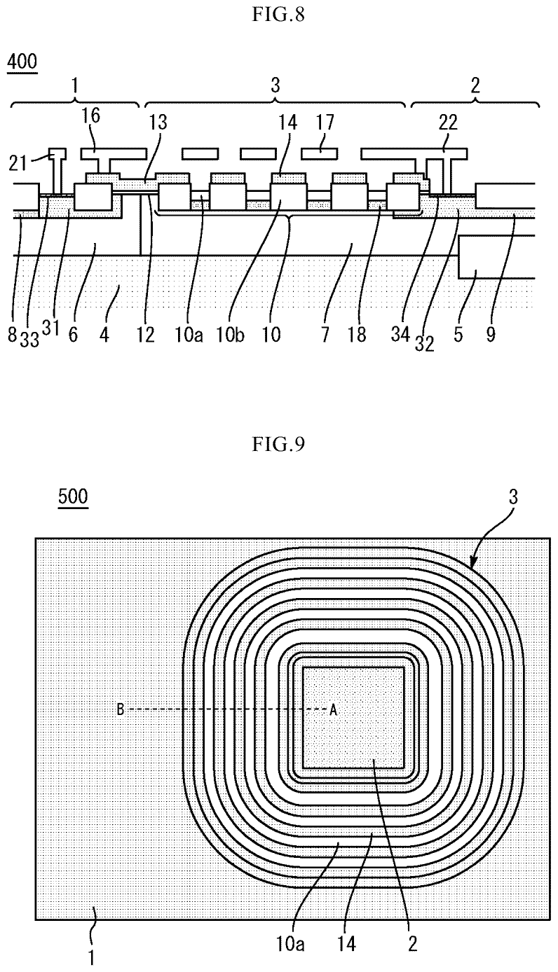

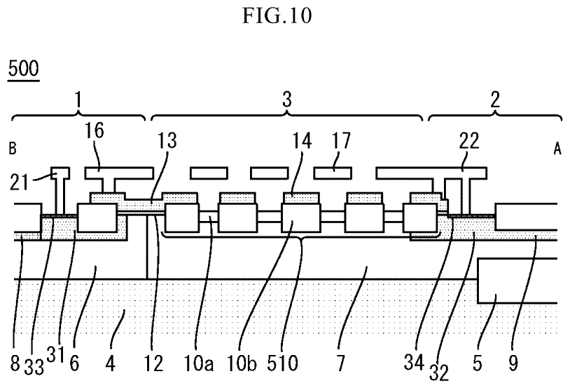

FIG. 9 is a plan view of a semiconductor device 500 according to Embodiment 5. FIG. 10 is a cross-sectional view obtained by cutting FIG. 9 along line A-B. In this embodiment, the RESURF region 7, that is, the high breakdown voltage isolation region 3, is provided so as to surround the high voltage region 2 in a plan view. Further, the low voltage region 1 is provided so as to surround the RESURF region 7. Further, the oxide film 510 includes a plurality of first portions 10a and a plurality of second portions 10b surrounding the high voltage region 2 in a plan view. The plurality of first portions 10a and the plurality of second portions 10b are alternately provided concentrically so as to surround the high voltage region 2 in a plan view. In FIG. 9, wiring such as the field plate 17 is omitted.

In the present embodiment, the field plate 14 on the second portion 10b can also be arranged concentrically. Therefore, the field plate 14 can be arranged without being divided in the circumferential direction. Therefore, the concern about a breakdown voltage decrease of the MOSFET can be reduced.

### Embodiment 6

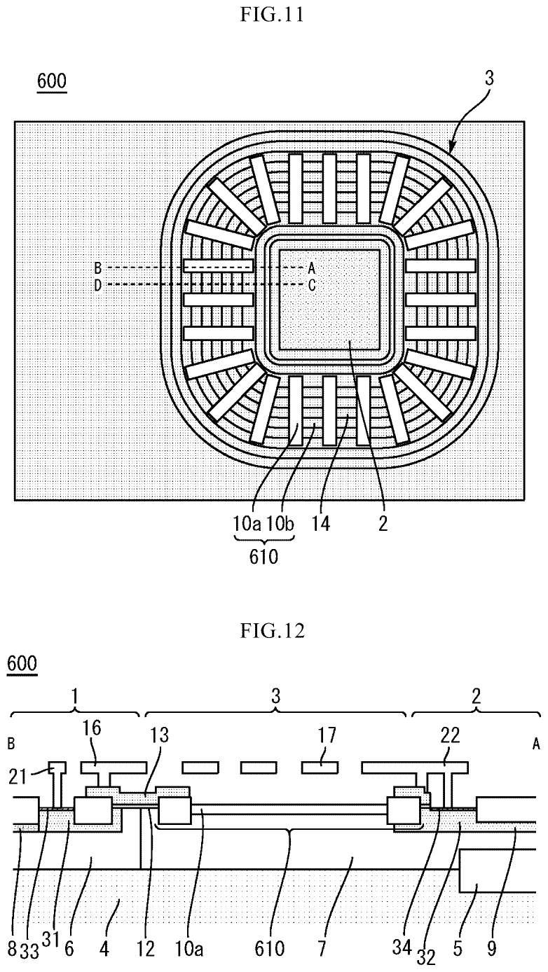

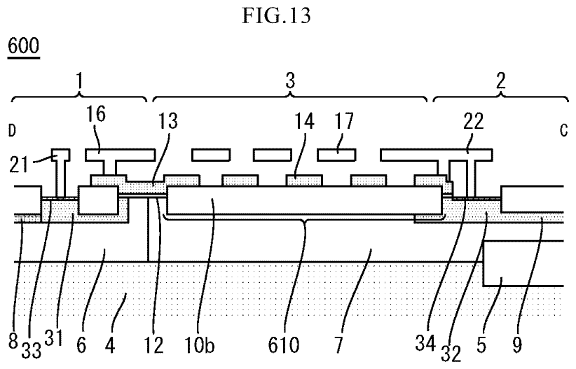

FIG. 11 is a plan view of a semiconductor device 600 according to Embodiment 6. FIG. 12 is a cross-sectional view obtained by cutting FIG. 11 along line A-B. FIG. 13 is a cross-sectional view obtained by cutting FIG. 11 along line C-D. In the present embodiment, the RESURF region 7, that is, the high breakdown voltage isolation region 3, is provided so as to surround the high voltage region 2 in a plan view. Further, the low voltage region 1 is provided so as to surround the RESURF region 7.

The oxide film 610 of the present embodiment includes a plurality of first portions 10a and a plurality of second portions 10b surrounding the high voltage region 2 in a plan view. The plurality of first portions 10a are provided radially around the high voltage region 2 in a plan view. Each first portion 10a is provided linearly. The first portions 10a and the second portions 10b are arranged alternately in the circumferential direction. In FIG. 11, the wiring of the field plate 17 and the like is omitted.

In the present embodiment, the area of the first portion 10a can be increased, and the on-resistance of the MOSFET can be further reduced. Further, the field plate 14 provided on the second portion 10b is also provided so as to surround the high voltage region 2, but is divided on the first portion 10a. Thereby, the decrease in withstand voltage can be suppressed.

### Embodiment 7

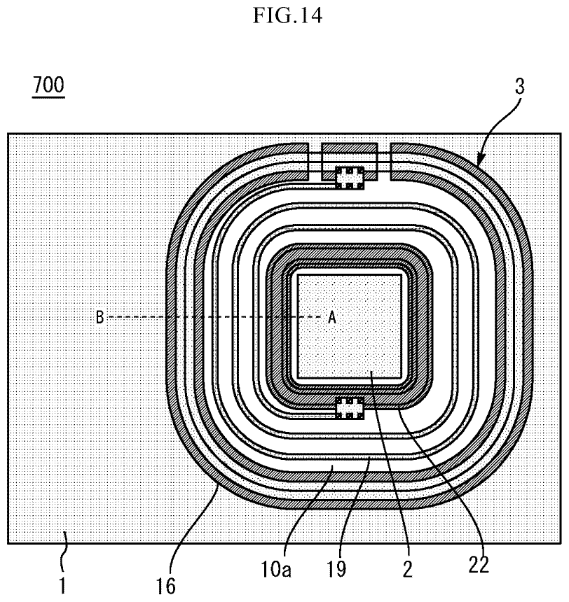

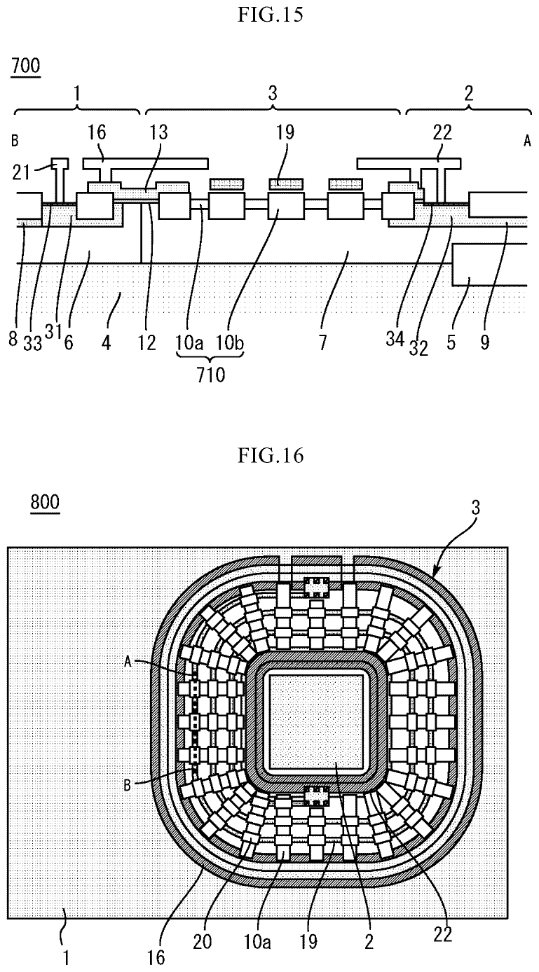

FIG. 14 is a plan view of a semiconductor device 700 according to Embodiment 7. FIG. 15 is a cross-sectional view obtained by cutting FIG. 14 along the line A-B. In the present embodiment, the RESURF region 7, that is, the high breakdown voltage isolation region 3, is provided so as to surround the high voltage region 2 in a plan view. Further, the low voltage region 1 is provided so as to surround the RESURF region 7.

An oxide film 710 of the present embodiment has a first portion 10a and a second portion 10b surrounding the high voltage region 2 in a plan view. In a plan view, the second portion 10b and the field plate 19 are spirally arranged around the high voltage region 2. The first portion 10a is also spirally arranged around the high voltage region 2 in a region without the field plate 19. This can suppress a breakdown voltage decrease.

As described above, in the present embodiment, the resistive field plate 19 is provided instead of the capacitively coupled field plates 14, 17 of Embodiment 1. The field plate 19 is, for example, a polysilicon thin film whose resistance value is adjusted by ion implantation. As shown in FIG. 15, the field plate 17 is not provided above the field plate 19. One end of the field plate 19 is connected to the drain electrode 22, and the other end is connected to the aluminum wiring 16.

### Embodiment 8

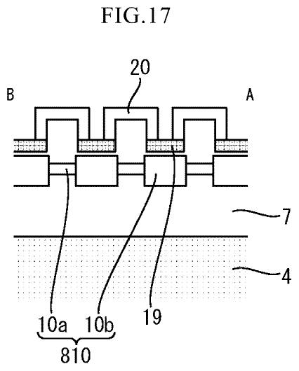

FIG. 16 is a plan view of a semiconductor device according to Embodiment 8. FIG. 17 is a cross-sectional view obtained by cutting FIG. 16 along line A-B. In the present embodiment, the RESURF region 7, that is, the high breakdown voltage isolation region 3, is provided so as to surround the high voltage region 2 in a plan view. Also, the low voltage region 1 is provided so as to surround the RESURF region 7.

The oxide film 810 according to the present embodiment has a plurality of first portions 10a and a plurality of second portions 10b surrounding the high voltage region 2 in a plan view. In a plan view, the plurality of first portions 10a are provided radially with the high voltage region 2 as the center. Each first portion 10a is provided linearly. Moreover, the first portions 10a and the second portions 10b are arranged alternately in the circumferential direction. That is, the first portions 10a and the second portions 10b are spirally connected with the high voltage region 2 as the center.

In a plan view, the field plate 19 is provided in a spiral shape around a high voltage region 2. The field plate 19 is provided on the second portion 10b along the oxide film 810. The spiral field plate 19 is interrupted directly above the plurality of first portions 10a, and is divided into a plurality of portions. The plurality of portions of the field plate 19 are connected by wiring 20 that straddles the plurality of first portions 10a. That is, the field plate 19 and the wiring 20 form a spiral. The wiring 20 is, for example, a jumper wire. One end of the wiring formed by the field plate 19 and the wiring 20 is connected to the drain electrode 22, and the other end is connected to the aluminum wiring 16.

In the present embodiment, by radially arranging the first portion 10a around the high voltage region 2, the area of the first portion 10a can be increased, and the on-resistance of the MOSFET can be reduced. In addition, by dividing the field plate 19 above the first portion 10a and crossing over the first portion 10a with the wiring 20, a decrease in breakdown voltage can be suppressed.

The technical features described in each embodiment may be combined and used as appropriate.

Hereinafter, various aspects of the present disclosure will be collectively described as appendixes.

### (Appendix 1)

A semiconductor device comprising:
a semiconductor substrate of a first conductivity type;
a low voltage region provided on an upper surface side of the semiconductor substrate;
a high voltage region provided on the upper surface side of the semiconductor substrate;
a RESURF region of a second conductivity type provided on the upper surface side of the semiconductor substrate and separating the low voltage region and the high voltage region;
a source electrode electrically connected to the low voltage region;
a drain electrode electrically connected to the high voltage region;
a gate electrode connected to the upper surface of the semiconductor substrate via a gate oxide film between the low voltage region and the high voltage region;
an oxide film provided on an upper surface of the RESURF region; and
a first field plate provided on an upper surface of the oxide film, wherein
the oxide film includes a first portion and a second portion that protrudes toward the RESURF region with respect to the first portion and is thicker than the first portion, and
the first field plate is provided so as to expose the first portion.

### (Appendix 2)

The semiconductor device according to appendix 1, wherein the first field plate is not provided on an upper surface of the first portion.

### (Appendix 3)

The semiconductor device according to appendix 1 or 2, wherein the first portion is a layer of a same type as the gate oxide film.

### (Appendix 4)

The semiconductor device according to appendix 3, wherein the first portion has a same thickness as the gate oxide film.

### (Appendix 5)

The semiconductor device according to any one of appendixes 1 to 4, further comprising a second field plate provided above the first field plate, wherein,
the first field plate and the second field plate are capacitively coupled.

### (Appendix 6)

The semiconductor device according to any one of appendixes 1 to 5, further comprising a semiconductor layer of the second conductivity type, which is provided on the upper surface side of the RESURF region and directly below the first portion, and has a higher concentration than the RESURF region.

### (Appendix 7)

The semiconductor device according to any one of appendixes 1 to 6, wherein, in a plan view, the RESURF region is provided so as to surround the high voltage region, and the low voltage region is provided so as to surround the RESURF region, and
in the plan view, a plurality of the first portions and a plurality of the second portions are alternately provided concentrically so as to surround the high voltage region.

### (Appendix 8)

The semiconductor device according to any one of appendixes 1 to 6, wherein, in a plan view, the RESURF region is provided so as to surround the high voltage region, and the low voltage region is provided so as to surround the RESURF region, and
in the plan view, a plurality of the first portions are radially provided around the high voltage region.

### (Appendix 9)

The semiconductor device according to appendix 8, wherein the first field plate is spirally provided around the high voltage region in the plan view.

### (Appendix 10)

The semiconductor device according to appendix 9, wherein the first field plate provided spirally is interrupted directly above the plurality of the first portions and divided into a plurality of portions, and
the plurality of portions of the first field plate are connected to each other by wiring that crosses over the plurality of the first portions.

### (Appendix 11)

The semiconductor device according to any one of appendixes 1 to 6, wherein in a plan view, the RESURF region is provided so as to surround the high voltage region, and the low voltage region is provided so as to surround the RESURF region, and
in the plan view, the second portion and the first field plate are spirally provided around the high voltage region.

### (Appendix 12)

The semiconductor device according to any one of appendixes 1 to 11, wherein the semiconductor substrate is made with a wide bandgap semiconductor.

### (Appendix 13)

The semiconductor device according to appendix 12, wherein the wide bandgap semiconductor is silicon carbide, a gallium nitride-based material, or diamond. In the semiconductor device according to the present disclosure, the first field plate is provided so as to expose the first portion of the oxide film that is thinner than the second portion. Therefore, a decrease in breakdown voltage can be suppressed.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2025-055258, filed on Mar. 28, 2025 including specification, claims, drawings and summary, on which the Convention priority of the present application is based, are incorporated herein by reference in its entirety.

1. A semiconductor device comprising:
a semiconductor substrate of a first conductivity type;
a low voltage region provided on an upper surface side of the semiconductor substrate;
a high voltage region provided on the upper surface side of the semiconductor substrate;
a RESURF region of a second conductivity type provided on the upper surface side of the semiconductor substrate and separating the low voltage region and the high voltage region;
a source electrode electrically connected to the low voltage region;
a drain electrode electrically connected to the high voltage region;
a gate electrode connected to the upper surface of the semiconductor substrate via a gate oxide film between the low voltage region and the high voltage region;
an oxide film provided on an upper surface of the RESURF region; and
a first field plate provided on an upper surface of the oxide film, wherein
the oxide film includes a first portion and a second portion that protrudes toward the RESURF region with respect to the first portion and is thicker than the first portion, and
the first field plate is provided so as to expose the first portion.

2. The semiconductor device according to claim 1, wherein the first field plate is not provided on an upper surface of the first portion.

3. The semiconductor device according to claim 1, wherein the first portion is a layer of a same type as the gate oxide film.

4. The semiconductor device according to claim 3, wherein the first portion has a same thickness as the gate oxide film.

5. The semiconductor device according to claim 1, further comprising a second field plate provided above the first field plate, wherein,
the first field plate and the second field plate are capacitively coupled.

6. The semiconductor device according to claim 1, further comprising a semiconductor layer of the second conductivity type, which is provided on the upper surface side of the RESURF region and directly below the first portion, and has a higher concentration than the RESURF region.

7. The semiconductor device according to claim 1, wherein, in a plan view, the RESURF region is provided so as to surround the high voltage region, and the low voltage region is provided so as to surround the RESURF region, and
in the plan view, a plurality of the first portions and a plurality of the second portions are alternately provided concentrically so as to surround the high voltage region.

8. The semiconductor device according to claim 1, wherein, in a plan view, the RESURF region is provided so as to surround the high voltage region, and the low voltage region is provided so as to surround the RESURF region, and
in the plan view, a plurality of the first portions are radially provided around the high voltage region.

9. The semiconductor device according to claim 8, wherein the first field plate is spirally provided around the high voltage region in the plan view.

10. The semiconductor device according to claim 9, wherein the first field plate provided spirally is interrupted directly above the plurality of the first portions and divided into a plurality of portions, and
the plurality of portions of the first field plate are connected to each other by wiring that crosses over the plurality of the first portions.

11. The semiconductor device according to claim 1, wherein in a plan view, the RESURF region is provided so as to surround the high voltage region, and the low voltage region is provided so as to surround the RESURF region, and
in the plan view, the second portion and the first field plate are spirally provided around the high voltage region.

12. The semiconductor device according to claim 1, wherein the semiconductor substrate is made with a wide bandgap semiconductor.

13. The semiconductor device according to claim 12, wherein the wide bandgap semiconductor is silicon carbide, a gallium nitride-based material, or diamond.
